(19) United States
(12) Patent Application Publication
(10) Pub. No.: US 2010/0079642 A1
(43) Pub. Date: Apr. 1, 2010

(54) Optical element wafer and method for manufacturing optical element wafer, optical element, optical element module, electronic element wafer module, electronic element module, and electronic information device

(75) Inventors: Hideyuki Kurimoto, Osaka-shi (JP); Yuji Yano, Osaka-shi (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 12/585,769

(22) Filed: Sep. 24, 2009

(30) Foreign Application Priority Data
Sep. 26, 2008 (JP) 2008-249253
Aug. 28, 2009 (JP) 2009-199032

(51) Int. Cl. H04N 5/335; B29D 11/00; G02B 3/08; G02B 7/00; H01L 31/12

(52) U.S. Cl. 348/294; 264/1.1; 264/1.32; 359/619; 359/811; 359/601; 257/80; 257/E31.095; 348/E05.091

(57) ABSTRACT

A method for manufacturing an optical element wafer according to the present invention, in which a plurality of optical elements are arranged in two dimensions, includes: a replica forming step of forming a replica, in which an optical element shape is formed on a front surface side, in each of a plurality of recesses formed in a base; a stamper mold forming step of forming a stamper mold using the optical element shape of the replica; and an optical element wafer forming step of transferring the optical element shape to an optical element material using the stamper mold to form an optical element wafer.

This nonprovisional application claims priority under 35 U.S.C. §119(a) to Patent Applications No. 2008-249253 filed in Japan on Sep. 26, 2008, and No. 2009-199032 filed in Japan on Aug. 28, 2009, the entire contents of which are hereby incorporated by reference.

### BACKGROUND OF THE INVENTION

1. Field of the Invention

The present invention relates to: an optical element wafer, such as a lens wafer or an optical function element wafer, including a plurality of lenses as a plurality of optical elements for focusing incident light; a method for manufacturing the optical element wafer; an optical element individualized by simultaneous cutting from the optical element wafer; an optical element module individualized by simultaneous cutting from an optical element wafer module in which the plurality of optical element wafers are laminated; an electronic element wafer module, such as a sensor wafer module, which is a combination of an optical element or an optical element module and an image capturing element wafer provided with a plurality of image capturing elements for performing a photoelectric conversion on and capturing an image of image light from a subject; an electronic element module individualized by simultaneous cutting from the electronic element wafer module or in which the optical element or the optical element module is modularized with an electronic element; and an electronic information device, such as a digital camera (e.g., a digital video camera or a digital still camera), an image input camera, a scanner, a facsimile machine, a camera-equipped cell phone device and a television telephone device, including the sensor module as an electronic element module used as an image input device in an image capturing section thereof.

2. Description of the Related Art

As a conventional optical element wafer of the above type, a lens wafer with a plurality of convex lenses arranged in a matrix therein is positioned for focusing light to image capturing elements of an image capturing element wafer, and they are laminated and combined together as a camera module.

Reference 1 discloses a method for manufacturing a convex lens wafer as the optical element wafer.

FIG. 9 is a schematic view illustrating the method for manufacturing the conventional convex lens wafer disclosed in Reference 1.

In FIG. 9, in a conventional reference grid manufacturing apparatus 100, an light curing resin 105 is interposed between a fine concave-convex pattern 102 of a flat plate transfer master 101 and a forming flat surface 104 of a replica base 103; and while the fine concave-convex pattern 102 is pressed against the light curing resin 105, the light curing resin 105 is cured by the irradiation of ultraviolet rays from the bottom of the light curing resin 105 by an ultraviolet ray light source 106. Consequently, a fine concave-convex pattern, which is an imprint of the fine concave-convex pattern 102, is completed on the upper surface of the light curing resin 105. Thus, in the method for forming the fine concave-convex pattern 102 by using the conventional reference grid manufacturing apparatus 100, it becomes possible to process the fine concave-convex pattern 102 with high accuracy and efficiency regardless of the size of the reference grid.

One exemplary process of a method for manufacturing the conventional convex lens wafer will be described in detail with reference to FIGS. 10(a) to 10(d) and FIGS. 11(a) to 11(c).

FIGS. 10(a) to 10(d) are each an essential part longitudinal cross sectional view describing a metal mold forming process for manufacturing the conventional convex lens wafer. FIGS. 11(a) to 11(c) are each an essential part longitudinal cross sectional view describing a manufacturing process for the conventional convex lens wafer.

As illustrated in a replica mold forming step of FIG. 10(a), a resin material 202 is delivered to a predetermined position on a base 201, which is formed of a glass substrate or a silicon substrate. The resin material 202 is pressed from the above using a master metal mold 203. As a result, a lower surface shape of the master metal mold 203 is transferred to the upper surface of the resin material 202 to form a resin replica 204. This process is repeated to form a plurality of replica molds of the resin replica 204 on the base 201 as illustrated in FIG. 10(b) .

As illustrated in FIG. 10(c), using the plurality of replica molds of the resin replica 204, the plurality of replica molds of the resin replica 204 on the base 201 are transferred to a stamper mold 205 of an upper metal mold of a wafer size.

As illustrated in FIG. 10(d), the stamper mold 205 of a wafer size is removed from the plurality of replica molds of the resin replica 204 on the base 201, to obtain the stamper mold 205 of an upper metal mold. Similar to this process, as illustrated in FIG. 11(a), the plurality of replica molds of the resin replica 204 formed on the base 201 are transferred to a stamper 206 of a lower metal mold, and subsequently, the replica molds are removed therefrom to obtain the stamper mold 206 of the lower metal mold.

As illustrated in FIG. 11(a), an appropriate amount of a forming resin 207 for forming a lens is delivered to the center position of the stamper mold 206 of the lower metal mold. The forming resin 207 is pressed from the top using the stamper mold 205 of the upper metal mold, and the forming resin 207 is put between the stamper molds 205 and 206 from the top and bottom to press-form a lens wafer 208 as illustrated in FIG. 11(b). During the process, the forming resin 207 is pressed to be expanded to obtain a desired lens thickness by the controlling of the upper and lower metal molds.

After the forming resin 207 is cured, the upper and lower stamper molds 205 and 206 are released and a desired lens wafer 208 is removed from the upper and lower metal molds as illustrated in FIG. 11(c). Thus, the lens wafer 208 with a desired shape can be obtained.

Reference 1: Japanese Laid-Open Publication No. 2006-64455

### SUMMARY OF THE INVENTION

In the conventional structure disclosed in Reference 1 described above, as illustrated in FIG. 12, when releasing the master metal mold 203 after the forming of the resin replica 204, the resin replica 204 is stuck to the master metal mold 203 and the resin is peeled off at the interface of the resin replica 204 and the base 201. Further, when an anchor coat material 204a is applied on the surface of the base 201, the resin replica 204 is adhered more closely to the anchor coat material 204a. On the other hand, the material may be peeled off at the interface of the anchor coat material 204a and the base 201, or a crack 204b may occur in the resin replica 204 itself.

When the resin replica 204 is individually formed using the master metal mold 203, the shape of the side surface of the formed resin replica 204 may not be formed perpendicularly due to the influence of the wet condition of the surfaces of the base 201 and the master metal mold 203 as well as the pressure when forming and the viscosity of the resin material 202. For example, as illustrated in FIG. 13(a), a problem may occur at the later releasing of stamper mold 205 due to an expansion 204c of the side surface of the resin replica 204, a recess 204d of the side surface of the resin replica 204 or a reversed tapered shape 204e of the side surface of the resin replica 204. That is, when the stamper mold 205 is released from the resin replica 204 after the formation of the stamper mold 205, the stamper mold 205 may cut into the side surface of the resin replica 204. Consequently, as illustrated in FIGS. 13(b) and 13(c), a poor mold release may occur where the resin replica 204 is lifted up together with the stamper mold 205, or a crack may occur in the resin replica 204 when the mold is forcibly released, resulting in a residue of the resin in the stamper mold 205.

Further, as illustrated in FIGS. 14(a) and 14(b), the thickness of a resin portion 208a in between adjacent resin patterns becomes thinner as the thickness of the resin becomes thicker at the replica forming of the resin replica 204. Therefore, a problem with regard to the strength may occur when a particularly large resin plate of the lens wafer 208 is manufactured. Further, as illustrated in FIG. 14(a), when the forming resin 207 is pressed and expanded by putting the forming resin 207 between the stamper molds 205 and 206 from the top and bottom, it is difficult for air within the forming resin 207 and air in the stamper molds 205 and 206 to be released, resulting in a tendency of air bubbles in the lens wafer 208, which is a resin plate. If the air bubbles remain in the lens function portion of the lens wafer 208, there will be a functional problem when focusing light onto image capturing elements.

The present invention is intended to solve the conventional problems described above. The objective of the present invention is to provide an optical element wafer, such as a lens wafer, and a method for manufacturing the optical element wafer when the resin replica is formed with accuracy to form the upper and lower stamper molds with accuracy, and when the large-sized lens wafer is formed, which is able to solve problems, such as the strength issue and residual air bubbles; an optical element individualized by simultaneous cutting from the optical element wafer; an optical element module individualized by simultaneous cutting from an optical element wafer module in which the plurality of optical element wafers are laminated; an electronic element wafer module, which is a combination of the optical element or optical element module and the electronic element wafer; an electronic element module individualized from the electronic element wafer module by simultaneous cutting or in which the optical element or the optical element module is modularized with an electronic element; and an electronic information device, such as a camera-equipped cell phone device, including the electronic element module as a sensor module used in an image capturing section thereof.

A method for manufacturing an optical element wafer according to the present invention, in which a plurality of optical elements are arranged in two dimensions, includes: a replica forming step of forming a replica, in which an optical element shape is formed on a front surface side, in each of a plurality of recesses formed in a base; a stamper mold forming step of forming a stamper mold using the optical element shape of the replica; and an optical element wafer forming step of transferring the optical element shape to an optical element material using the stamper mold to form the optical element wafer, thereby achieving the objective described above.

Preferably, in a method for manufacturing the optical element wafer according to the present invention, the replica forming step includes: an upper replica forming step of forming an upper replica, in which an optical element shape is formed on a front surface side, in each of the plurality of recesses formed in the base; and a lower replica forming step of forming a lower replica, in which an optical element shape for aback surface is formed on a front surface side, in each of a plurality of recesses formed in another base.

Still preferably, in a method for manufacturing the optical element wafer according to the present invention, the replica forming step includes: a step of delivering a replica material in the plurality of recesses formed in the base; and an optical element shape transferring step of pressing the replica material using a master mold to transfer the optical element shape of the master mold to the front surface side of the replica material.

Still preferably, in a method for manufacturing the optical element wafer according to the present invention, part or all of a side surface of the replica is buried in each of the plurality of recesses carved in the base to form the replica.

Still preferably, in a method for manufacturing the optical element wafer according to the present invention, a depth of the recess in the base is set such that a contacting area of the base and the replica is larger than a contacting area of the replica and a master mold.

Still preferably, in a method for manufacturing the optical element wafer according to the present invention, a depth of the recess in the base is set such that a contacting area of the base and the replica is larger than a contacting area of the replica and the stamper mold.

Still preferably, in a method for manufacturing the optical element wafer according to the present invention, the stamper mold forming step includes: an upper stamper mold forming step of transferring the optical element shape of the upper replica to form an upper stamper mold; and a lower stamper mold forming step of transferring the optical element shape of the lower replica to form a lower stamper mold.

Still preferably, in a method for manufacturing the optical element wafer according to the present invention, the optical element wafer forming step includes: an optical element material pressing step of pressing the optical element material to a predetermined thickness using the upper stamper mold and the lower stamper mold; and an optical element material curing step of curing the optical element material by light or heat.

Still preferably, in a method for manufacturing the optical element wafer according to the present invention, the optical element is one or a plurality of lenses.

Still preferably, in a method for manufacturing the optical element wafer according to the present invention, the optical element is an optical function element that directs output light straight to be output and refracts and guides incident light in a predetermined direction.

An optical element wafer according to the present invention is manufactured using the method for manufacturing the optical element wafer according to the present invention, thereby achieving the objective described above.

An optical element wafer according to the present invention, in which a plurality of optical elements are arranged in two dimensions, includes: a plurality of optical element areas at least on either a front surface or a back surface of the optical element wafer; a planarized portion with a predetermined thickness provided on an outer circumference side of the optical element area, and wherein a thickness of the planarized portion between adjacent optical element areas and a thickness of a connecting portion between the planarized portions are within the ratio of 2:1 to an equal ratio, thereby achieving the objective described above.

Preferably, in an optical element wafer according to the present invention, the thickness of the planarized portion between the adjacent optical element areas is within the ratio of 4/3 or 3/4 to an equal ratio with the thickness of the connecting portion between the planarized portions.

Still preferably, in an optical element wafer according to the present invention, the optical element is one or a plurality of lenses.

Still preferably, in an optical element wafer according to the present invention, the optical element is an optical function element that directs output light straight to be output and refracts and guides incident light in a predetermined direction.

An optical element according to the present invention, which is individualized by cutting from the optical element wafer according to the present invention, includes: an optical surface at a center portion; and a spacer section with a predetermined thickness on an outer circumference side of the optical surface, thereby achieving the objective described above.

An optical element module according to the present invention is individualized by cutting an optical element wafer module, in which the plurality of optical element wafers according to the present invention are laminated with optical surfaces thereof being aligned to one another, thereby achieving the objective described above.

An optical element module according to the present invention further includes a light shielding holder for shielding an upper surface other than an upper most optical surface, and side surfaces of the plurality of optical elements, thereby achieving the objective described above.

An optical element module according to the present invention includes a light shielding holder for shielding an upper surface other than the optical surface, and side surfaces of the optical element according to the present invention, thereby achieving the objective described above.

An electronic element wafer module according to the present invention includes: an electronic element wafer in which a plurality of electronic elements are arranged, the electronic elements each including a penetrating electrode; a resin adhesion layer formed in a predetermined area on the electronic element wafer; a transparent support substrate covering the electronic element wafer and fixed on the resin adhesion layer; an optical element wafer according to the present invention, adhered and combined with the transparent support substrate such that each of the plurality of electronic elements corresponds to each optical element, thereby achieving the objective described above.

Preferably, in an electronic element wafer module according to the present invention, the optical element wafer is a lens wafer module constituted of three lenses of an aberration correction lens, a diffusion lens and a light focusing lens; in which planarized portions with a predetermined thickness are provided on an outer circumference side of each of the lenses is laminated in this order from the bottom.

Still preferably, in an electronic element wafer module according to the present invention, the electronic element is an image capturing element including a plurality of light receiving sections for performing a photoelectric conversion on and capturing an image of image light from a subject.

Still preferably, in an electronic element wafer module according to the present invention, each of said electronic elements is a light emitting element for generating output light and a light receiving element for receiving incident light.

An electronic element module according to the present invention is cut from the electronic element wafer module according to the present invention, for each or a plurality of the electronic element modules, thereby achieving the objective described above.

An electronic information device according to the present invention includes an electronic element module, which is individualized by being cut from the electronic element wafer module according to the present invention, used as a sensor module in an image capturing section, thereby achieving the objective described above.

An electronic information device according to the present invention includes an electronic element module, which is individualized by being cut from the electronic element wafer module according to the present invention, used in an information recording and reproducing section, thereby achieving the objective described above.

The functions of the present invention having the structures described above will be described hereinafter.

According to the present invention, a method for manufacturing an optical element wafer includes: a replica forming step of forming replicas with an optical element shape formed on a front surface side thereof, in a plurality of recesses formed in a base; a stamper mold forming step of forming a stamper mold using the optical element shape of the replica; and an optical element wafer forming step of transferring the optical element shape to an optical element material using the stamper mold to form the optical element wafer. Through the method, in the optical element wafer of the present invention, a plurality of optical element areas are formed at least on either of a front surface or a back surface of the wafer, and a planarized portion with a predetermined thickness is formed on an outer circumference side of the optical element area. The thickness of the planarized portion between adjacent optical element areas and the thickness of the connecting portion between the planarized portions are within the ratio of 2:1 to an equal ratio. Preferably, the thickness of the planarized portion between adjacent optical element areas is within the ratio of 4/3 or 3/4 to an equal ratio with the thickness of the connecting portion between the planarized portions.

Therefore, part or all of the side surface of the replica is buried in the respective recesses carved in the base to form the replica, so that the contacting area of the base and the replica becomes larger than the contacting area of the replica and the master mold and the contacting area of the base and the replica becomes larger than the contacting area of the replica and the stamper mold. Thus, release of the master mold and stamper mold can be performed smoothly and the thickness of the connecting portion between the planarized portions becomes thicker by an amount equal to the depth of the recess. As a result, it becomes possible to accurately form the replica and accurately form the upper and lower stamper molds. Furthermore, it becomes possible to solve the problem of the strength issue in forming a large-sized lens wafer. Furthermore, it becomes possible to solve the problem of residual the air bubbles by reducing the difference in level on the surface.

According to the present invention with the structure described above, part or all of the side surface of the replica is buried in the respective recesses carved in the base to form the replica, so that the contacting area of the base and the replica becomes larger than the contacting area of the replica and the master mold and the contacting area of the base and the replica becomes larger than the contacting area of the replica and the stamper mold. Thus, the release of the master mold and stamper mold can be performed smoothly and the thickness of the connecting portion between the planarized portions becomes thicker by an amount equal to the depth of the recess, so that it becomes possible to accurately form the replica and accurately form the upper and lower stamper molds; it becomes possible to solve the problem of the strength issue when forming a large-sized lens wafer; and it becomes possible to solve the problem of residual the air bubbles by reducing the difference in level on the surface.

These and other advantages of the present invention will become apparent to those skilled in the art upon reading and understanding the following detailed description with reference to the accompanying figures.

### BRIEF DESCRIPTION OF THE DRAWINGS

FIG. 1 is an essential part longitudinal cross sectional view illustrating an exemplary structure of a lens wafer according to Embodiment 1 of the present invention.

FIG. 2 is an essential part longitudinal cross sectional view describing a replica forming process of a method for manufacturing the lens wafer of FIG. 1.

FIG. 3 is a perspective view schematically illustrating an exemplary diagrammatic structure of a carved base used for the replica forming process of FIG. 2.

FIGS. 4(a) to 4(c) are each an essential part longitudinal cross sectional view describing a metal mold forming process to manufacture the lens wafer of FIG. 3.

FIGS. 5(a) and 5(b) are each an essential part longitudinal cross sectional view describing a forming process of the lens wafer of FIG. 1.

FIG. 6(a) is a longitudinal cross sectional view illustrating an exemplary variation of a lens individualized from the lens wafer of FIG. 1. FIG. 6(b) is a longitudinal cross sectional view illustrating an exemplary lens module in which a plurality of lenses are laminated. FIG. 6(c) is a top view of the second lens of FIG. 6(b). FIG. 6(d) is a top view of the first lens of FIG. 6(b). FIG. 6(e) is a longitudinal cross sectional view of a combination of the first lens and a light shielding holder. FIG. 6(f) is a longitudinal cross sectional view of a lens module of a combination of the exemplary variation of the lens module of FIG. 6(b) and the light shielding holder. FIG. 6(g) is a longitudinal cross sectional view illustrating an exemplary essential part structure of a lens wafer module in which a light shielding holder wafer, a first lens wafer and a second lens wafer are laminated.

FIG. 7 is a longitudinal cross sectional view illustrating an exemplary essential part structure of a sensor module according to Embodiment 3 of the present invention.

FIG. 8 is a block diagram schematically illustrating an exemplary configuration of an electronic information device of Embodiment 4 of the present invention, including a solid-state image capturing apparatus including the sensor module according to Embodiment 3 in which the lens module and the image capturing element chip are combined with each other, or the sensor module according to Embodiment 2 in which the lens module and the image capturing element chip according to Embodiment 1 are combined with each other, used in an image capturing section thereof.

FIG. 9 is a schematic view illustrating a method for manufacturing a conventional convex lens wafer, the method being disclosed in Reference 1.

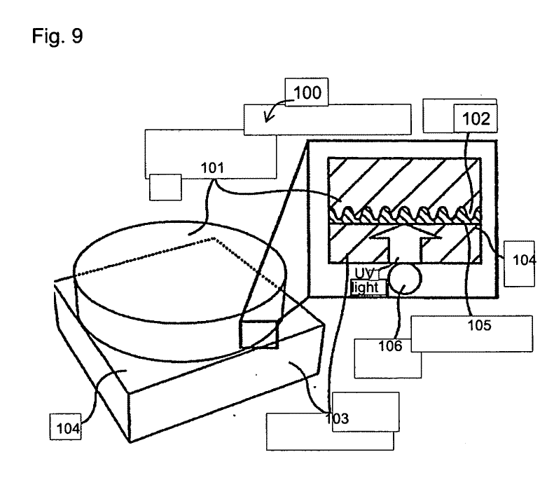

FIGS. 10(a) to 10(d) are each an essential part longitudinal cross sectional view describing a metal mold forming process to manufacture a conventional convex lens wafer.

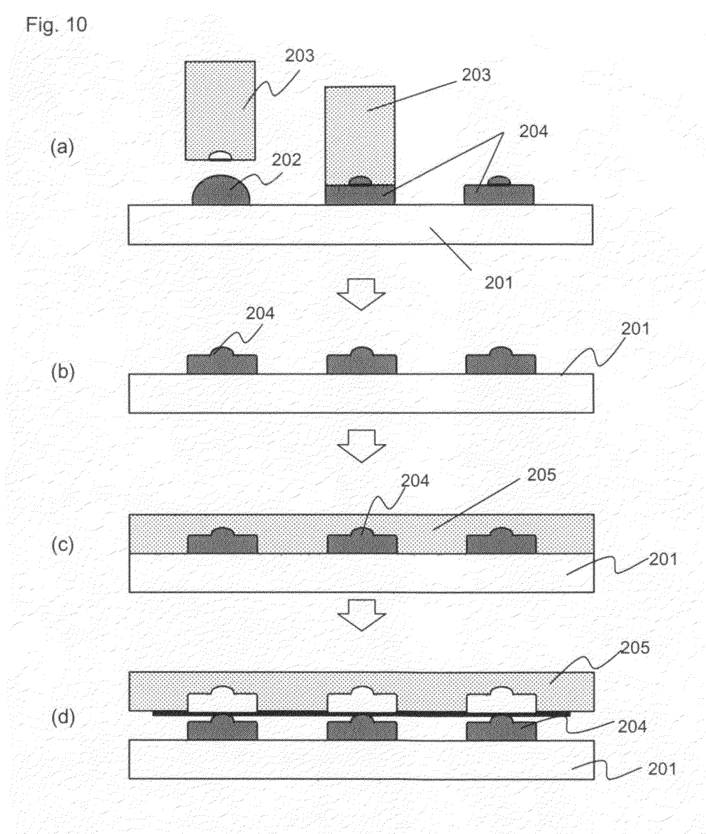

FIGS. 11(a) to 11(c) are each an essential part longitudinal cross sectional view describing a forming process of a conventional convex lens wafer.

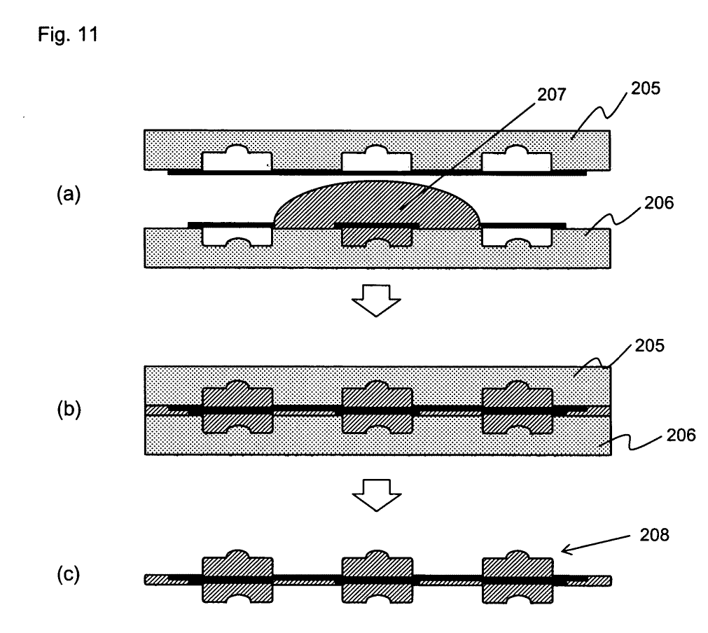

FIG. 12 is an essential part longitudinal cross sectional view describing a replica forming step to describe a problem that occurs when releasing a master metal mold after a resin replica is formed.

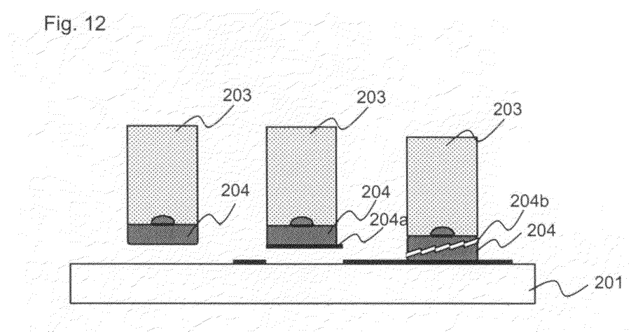

FIGS. 13(a) to 13(c) are each an essential part longitudinal cross sectional view describing a stamper mold forming step describing a problem in releasing a stamper mold from a resin replica.

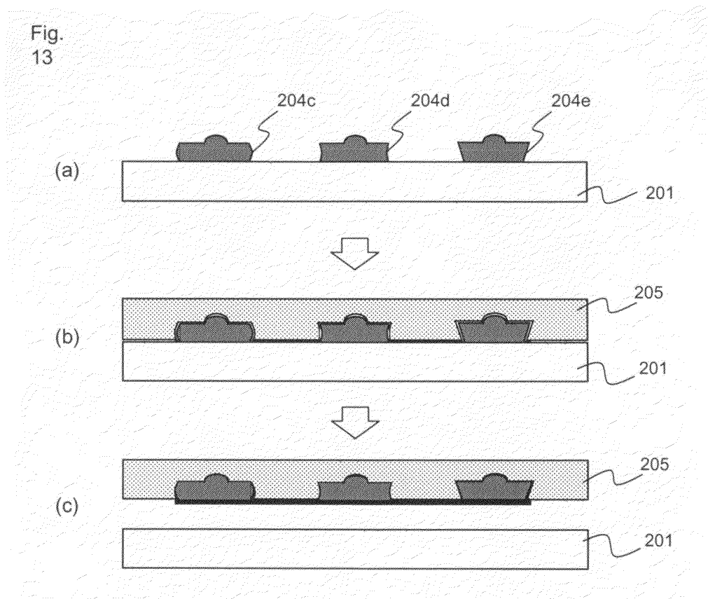

FIGS. 14(a) and 14(b) are each an essential part longitudinal cross sectional view describing a lens wafer forming step to describe a problem that occurs when forming a lens wafer.

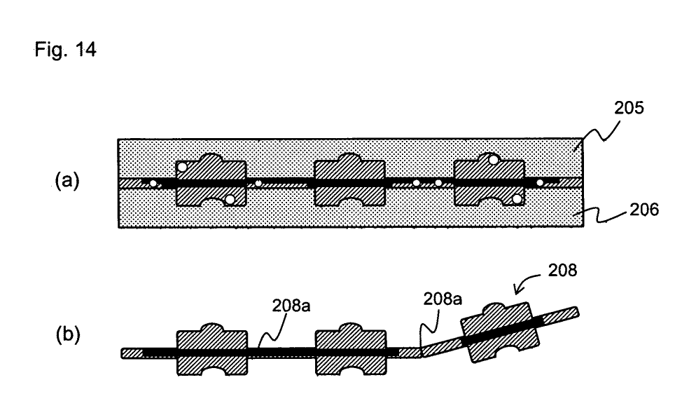

1 lens wafer
10, 10A sensor module
11 base
11a recess
12 resin material
13 master metal mold
14 resin replica
15 upper stamper mold
16 lower stamper mold
20 image capturing element chip
21 image capturing element
22 penetrating electrode
23 pad
24 wiring layer
25 solder ball
30 resin adhesion layer
40 transparent support substrate
50 lens module
51 first lens
52 second lens
53 third lens
61, 62 adhesion layer
61A, 84, 84A, 84a first lens
85, 85A, 85a second lens
86, 86A lens module
87 light shielding holder
88, 89 lens module
90 electronic information device
91 solid-state image capturing apparatus
92 memory section
93 display section
94 communication section
95 image output section
A optical surface
B optical surface outer circumference end portion
DL dicing line
F1 planarized section
F2 annular protruded section

### DESCRIPTION OF THE PREFERRED EMBODIMENTS

Hereinafter, as Embodiment 1 of an optical element wafer and a method for manufacturing the optical element wafer according to the present invention, a case will be described in detail where the present invention is applied to a lens wafer and a method for manufacturing the lens wafer with reference to the accompanying figures. Further, as Embodiment 2 of an optical element individualized from the optical element wafer, and an optical element module individualized from an optical element wafer module in which the plurality of optical elements are laminated, a lens and a lens module will be described in detail with reference to the accompanying figures. Further, as Embodiment 3 of an electronic element module simultaneously cut from an electronic element wafer module according to the present invention, a case will be described in detail where the present invention is applied to a sensor module in which the lens wafer of Embodiment 1 is combined with an image capturing element wafer that includes a plurality of image capturing elements for performing a photoelectric conversion on and capturing an image of image light from a subject. Further, an electronic information device of Embodiment 4, such as a camera-equipped cell phone device and a television telephone device, including the sensor module or a sensor module using the optical element module according to Embodiment 2, used as an image input device thereof will be described in detail with reference to the accompanying figures.

### Embodiment 1

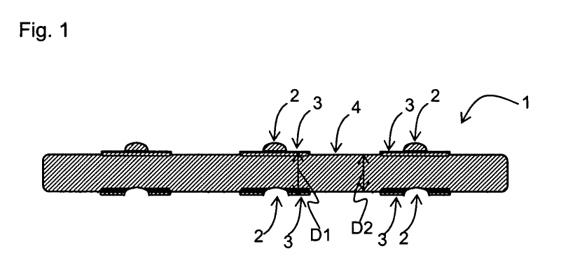

FIG. 1 is an essential part longitudinal cross sectional view illustrating an exemplary structure of a lens wafer according to Embodiment 1 of the present invention.

In FIG. 1, in a lens wafer 1 functioning as an optical element wafer of Embodiment 1, a plurality of lens areas 2 are formed as a plurality of optical element areas on either a front surface or a back surface thereof. A planarized portion 3 is disposed with a predetermined thickness on the outer circumference side of the lens area 2. A thickness D1 of the planarized portion 3 between adjacent lens areas 2 and a thickness D2 of a connecting portion 4 between the planarized portions 3 are within the ratio of 2:1 (2/1 or 1/2) to an equal ratio. Preferably, the thickness D1 of the planarized portion 3 between adjacent lens areas 2 is within the ratio of 4/3 (or 3/4) to an equal ratio with the thickness D2 of the connecting portion 4 between the planarized portions 3.

Herein, the resin thickness D2 between individual resin patterns in the lens area 2 functioning as an optical element area and the planarized portion 3 in the periphery thereof, is formed thick so as to be substantially as thick as (even in the thickness with) the resin thickness D1 of the resin pattern. As a result, a concave-convex shape of the front and back surfaces of the lens wafer 1 is reduced (the difference in level is reduced), which will lessen the obstruction of the flow of the resin and lessen the residual air bubbles in the lens wafer 1.

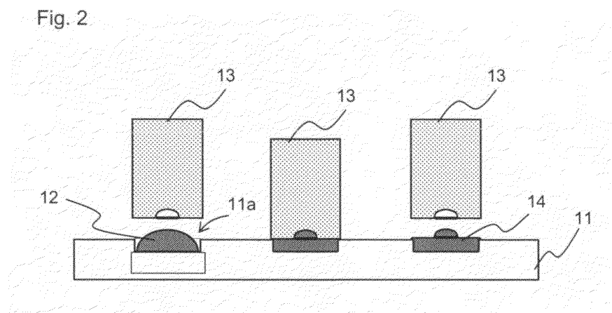

Each of the steps of a method for manufacturing the lens wafer 1 as an optical element wafer with the structure described above will be described in detail with reference to FIGS. 2 to 5.

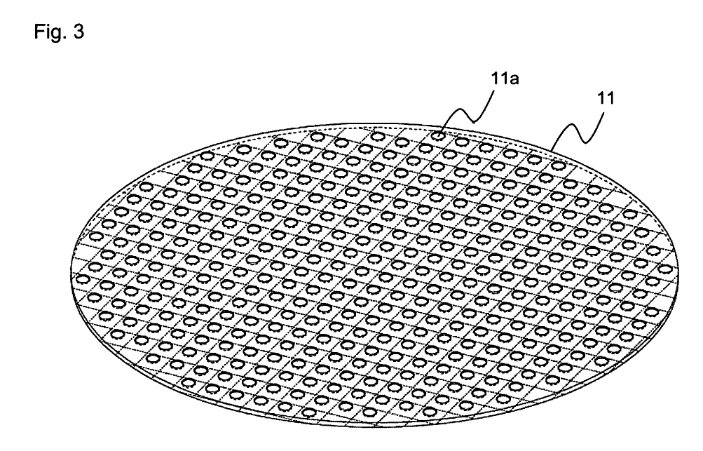

FIG. 2 is an essential part longitudinal cross sectional view describing a replica forming process of the method for manufacturing the lens wafer of FIG. 1. FIG. 3 is a perspective view schematically illustrating an exemplary diagrammatic structure of a carved base used for the replica forming process of FIG. 2.

A plurality of recesses 11a are arranged in a matrix on a surface of a base 11, as illustrated in FIG. 3. The base 11 is formed of a glass substrate, a silicon substrate or a resin substrate. First, a resin material 12 is delivered in each of the recesses 11a of the base 11, as illustrated in the replica mold forming step of FIG. 2. Next, the resin material 12 is pressed from above using the master metal mold 13 to transfer the predetermined lens form of the master metal mold. 13 onto the surface of the resin material 12, resulting in forming the resin replica 14. The steps will be successively repeated to form a plurality of replica molds of the resin replica 14 at equal intervals on the base 11.

Thus, the side surface of the resin replica 14 is buried in the carved shape (recess 11a) of the base 11, so that the resin material 12 of the resin replica 14 will have a larger contacting area with the base 11. Because of this and there is an anchoring effect by the side surface of the recess 11a (carved portion) of the base 11, the base 11 is more closely adhered to the resin material 12, and the conventional problems, such as resin cracks and peeling off of the resin, can be reduced when releasing of the master metal mold 13 from the resin replica 14.

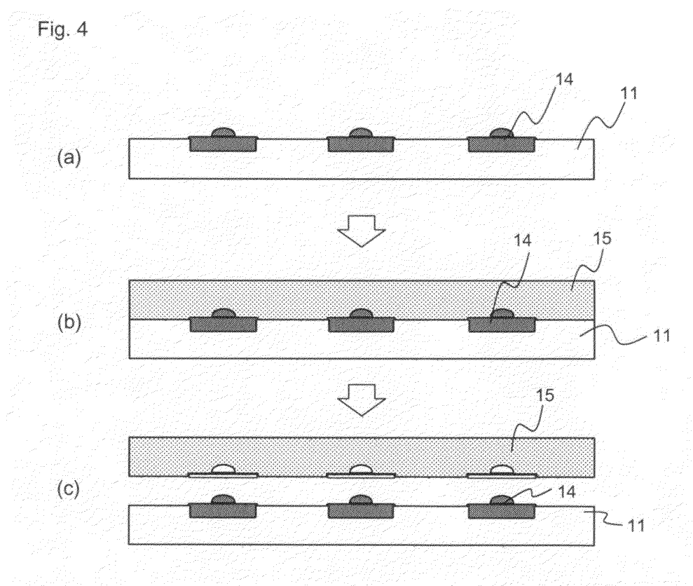

Next, as illustrated in FIGS. 4(a) and 4(b), using each replica mold of the plurality of resin replicas 14, which are buried in the recess 11a carved in the base 11, the replica mold of the plurality of resin replicas 14 on the base 11 is transferred to an upper stamper mold 15 of a wafer size as a lens surface shape. Further, as illustrated in FIG. 4(c), the upper stamper mold 15 is released from the plurality of replica molds of the resin replica 14 to obtain the stamper mold 15 of the upper metal mold. Similar to this process, the plurality of replica molds of the resin replica 14 formed on the base 11 are transferred to a stamper mold 16 to be described later, and subsequently, the stamper mold 15 is released from the replica molds to obtain the stamper mold 16 of the lower metal mold.

As described above, in forming the plurality of replica molds of the resin replica 14 on the base 11, the side surface of the replica mold of the resin replica 14 is buried in the recess 11a of the base 11 that has perpendicular side walls. As a result, the side surface of the resin replica 14 will not expand, become indented or have a reversed tapered shape due to the influence of the wet condition of the surfaces of the base 11 and the master metal mold 13 as well as the pressure at the forming and the viscosity of the resin material 12, as occurred in the conventional method. Instead, the resin material is formed perpendicular in the recess 11a of the base 11, which will make the releasing of the stamper molds 15 and 16 smooth in the latter process, and eliminate the poor mold release and the residual the resin inside the stamper molds 15 and 16 due to the forceful release.

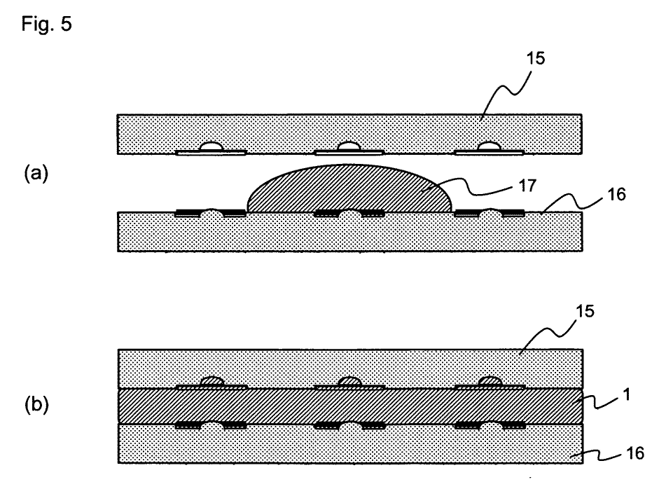

Subsequently, as illustrated in FIG. 5(a), an appropriate amount of a forming resin 17 for forming a lens is delivered to the center portion of the stamper mold 16 of the lower metal mold. Next, the forming resin 17 is pressed from the top using the stamper mold 15 of the upper metal mold, and the forming resin 17 is put between the stamper molds 15 and 16 from the top and bottom to press-form a lens wafer 1 as illustrated in FIG. 5(b). During the process, the forming resin 17 is pressed to be spread to obtain a desired lens thickness by the controlling of the upper and lower metal molds.

Subsequently, the formed forming resin 17 is cured by ultraviolet rays or heat, and the upper and lower stamper molds 15 and 16 are pulled apart in the vertical direction for mold release, and the desired lens wafer 1 is released from the upper and lower molds as illustrated in FIG. 1. Thus, the lens wafer 1, in which a plurality of desired lens shapes are regularly repeated, can be obtained.

That is, the method for manufacturing the lens wafer 1 as the optical element wafer of Embodiment 1 includes: a step of delivering the replica material in the plurality of recesses 11a formed in the base 11; an upper replica forming step of pressing the replica material using the master mold 13 to transfer the front surface lens shape of the master mold 13 to the surface of the replica material to form the upper resin replica 14; a step of delivering the replica material the plurality of recesses 11a formed in another base 11; a lower replica forming step of pressing the replica material using another master mold 13 to transfer the back surface lens shape of the master mold 13 to the surface of the replica material to form the lower resin replica 14; an upper stamper mold forming step of transferring the lens front surface shapes of the upper resin replicas 14 to form the upper stamper mold 15; a lower stamper mold forming step of transferring the lens back surface shapes of the lower resin replicas 14 to form the lower stamper mold 16; an optical element material pressing step of pressing the lens material to a predetermined thickness using the upper and lower stamper molds 15 and 16, and an optical element material curing step of curing the lens material by light or heat.

In this case, part or all of the side surface of the resin replica 14 is buried in the plurality of recesses 11a carved in the base 11 to form the resin replica 14. In addition, the depth of the recesses 11a of the base 11 is set such that the contacting area of the base 11 and the resin replica 14 is larger than the contacting area of the resin replica 14 and the master mold 13, and the contacting area of the base 11 and the resin replica 14 is larger than the contacting area of the resin replica 14 and the stamper molds 15 and 16.

As described above, in forming the resin replica 14 individually, the resin material 12, which forms the resin replica 14, is buried in the carved portion (recess 11a) of the base 11, so that the individual resins between the resin patterns become thick, and the resins between the resin patterns become uniform with the resin patterns. Therefore, in manufacturing the lens wafer 1, which is a large-sized resin plate, the strength is appropriate. In addition, in placing the forming resin 17 between the stamper molds 15 and 16 from the top and bottom to press and expand the forming resin 17, the stamper molds 15 and 16 have less inconsistency compared to the conventional technique, which will lessen the obstruction of the flow of the resin and lessen the residual air bubbles in the lens wafer 1.

In the manufacturing of the resin replica 14, the following characteristics are required in the base 11 in order to be used: (1) planarized characteristic that influences the variation of the inclination and height of a final lens; (2) selection of the material and characteristics of the replica resin material 12 (for the resin curing method that influences the stability of the shape); and (3) high adhesion with the resin for forming the replica mold of the resin replica 14. The carved portion (recess 11a) is formed in the base 11 for forming the resin replica, so that the controlling of the size of the resin replica 14, such as the diameter of the replica, becomes easy; the metal mold surface and the glass surface can be easily set parallel to each other, which will reduce the inclination of the shape. By the carved shape, the closely adhering area increases with the resin, so that close adhesion of the replica resin material 12 increases with respect to any materials.

In addition, the replica resin material 12 is buried in the carved portion (recess 11a) of the base 11. As a result, the difference in level between the surface of the resin replica 14 and the surface of the base 11 becomes smaller, the closely adhering area with the upper and lower stamper molds 15 and 16 becomes smaller after the upper and lower stamper molds 15 and 16 are formed, and the amount of the resin intruding into the concave-convex shape of the stamper molds 15 and 16 becomes less. Therefore, the release of the stamper molds 15 and 16 from the resin replica 14 will be easier.

Further, the replica resin material 12 is buried in the carved portion (recess 11a). Therefore, the difference in level becomes smaller between the surface of the resin replica 14 and the surface of the base 11, so that the lens resin plate becomes thick and uniform when the lens is formed using the upper and lower stamper molds 15 and 16, which leads to an ease of formation of the WL lens (wafer level lens; lens wafer).

### Embodiment 2

In Embodiment 2, a variation of a lens as an optical element, which is individualized from the lens wafer 1 as an optical element wafer formed by the upper and lower stamper molds 15 and 16 in Embodiment 1, will be described in detail. Furthermore, a variation of a lens module as an optical element module, in which the plurality of lenses are laminated, will be described in detail.

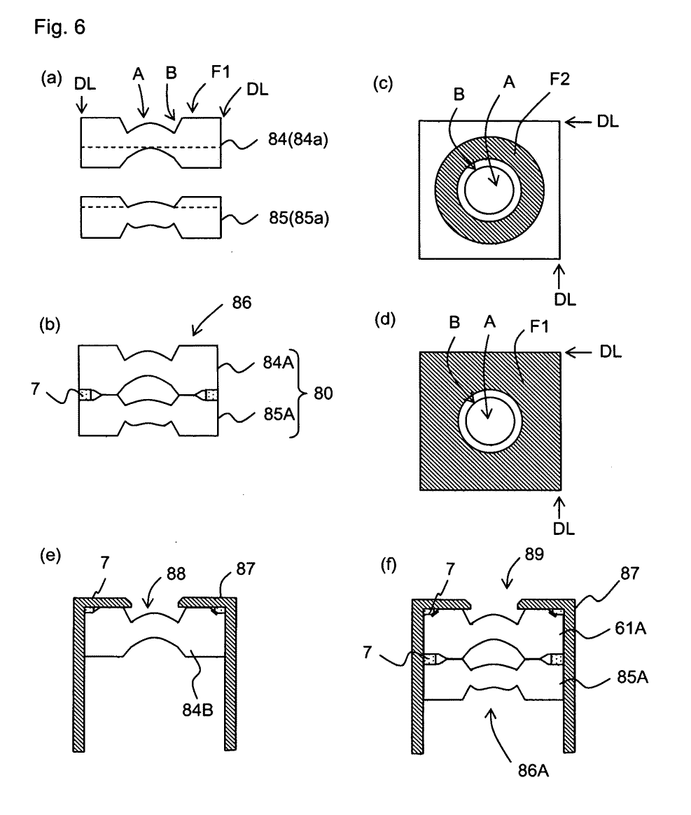

FIG. 6(a) is a longitudinal cross sectional view illustrating an exemplary variation of a lens individualized from the lens wafer of FIG. 1. FIG. 6(b) is a longitudinal cross sectional view illustrating an exemplary lens module in which a plurality of lenses are laminated. FIG. 6(c) is a top view of the second lens of FIG. 6(b). FIG. 6(d) is a top view of the first lens of FIG. 6(b). FIG. 6(e) is a longitudinal cross sectional view of a combination of the first lens and a light shielding holder. FIG. 6(f) is a longitudinal cross sectional view of a lens module of a combination of the exemplary variation of the lens module of FIG. 6(b) and the light shielding holder. FIG. 6(g) is a longitudinal cross sectional view illustrating an exemplary essential part structure of a lens wafer module in which a light shielding holder wafer 187B, a first lens wafer 65B and a second lens wafer 185B are laminated.

As illustrated in FIG. 6(a), a large number of first lenses 84 as well as a large number of second lenses 85 can be obtained by cutting along dicing lines DL the first lens wafer and the second lens wafer, which are formed using upper and lower metal molds that have different lens surfaces from those of the upper and lower stamper molds 15 and 16 of Embodiment 1. A spacer section with a predetermined thickness is disposed on the outer circumference side of an optical surface A of the center portion in the first and second lenses 84 and 85. As illustrated by the shaded portion of a quadrilateral on the outside and a circle on the inside in a plane view in FIG. 6(d), the spacer section is a planarized portion F1 which is protruded from a circular outer circumference end portion B surrounding the optical surface A that is higher than the convex shape of the optical surface A. In the first and second lenses 84 and 85, the optical surface A and the spacer section are simultaneously formed with a transparent resin material. In the second lens 85 of a quadrilateral in the plane view, the spacer section on the front surface side is an annular planarized portion F2 which is protruded from a circular outer circumference end portion B surrounding an optical surface A that is higher than the convex shape of the optical surface A. The surface of the annular protruded portion F2 is also a planarized surface.

Further, a lens module 86 illustrated in FIG. 6(b) can be obtained by simultaneously cutting along the dicing lines DL in the state where the first lens wafer, in which a plurality of first lenses 84A are formed, and the second lens wafer, in which a plurality of second lenses 85A are formed, are adhered on top of another by adhesive 7. Again, in the cutting stage, a cut-securing tape is adhered on the planarized section F1 of the lower second lens wafer, and a surface-protection tape for protecting the lens surface is adhered on the planarized section F1 of the upper first lens wafer. As a result, during the cutting stage, the respective lens optical surfaces of the first and second lenses 84A and 85A are sealed and protected by the cut-securing tape and the surface-protecting tape, so that the lens optical surfaces do not become dirty from the cutting water.

In this case, the annular planarized surface of the spacer section of the upper first lens 84A directly contacts with the annular planarized surface of the spacer section of the lower second lens 85A, and the adhesive 7 is provided in the space portion surrounded by the bottom portion on the further outer circumference side of each planarized surface, so that the first lens 84A is adhered to the second lens 85A.

Further, a first lens 84a illustrated by a dash line in FIG. 6(a) includes a planarized back surface, and the optical surface A and the planarized section F1 on the front surface, the planarized section F1 being more protruded than the optical surface A. In this case, the first lens 84a and the second lens 85 are provided together as a set. Further, the first lens 84 and the second lens 85a illustrated by a dash line are provided as a set. Even if the optical surface A of the front surface of the second lens 85a is protruded, it fits in the concave portion of the back surface of the first lens 84. The optical surface A and the planarized section F1, which is more protruded than the optical surface A, are provided only on the back surface of the second lens 85a. Because of this, each lens optical surface A does not become dirty from the cutting water, as described above.

In summary, it is proper as long as the optical surface A and the more protruded, protruded section F2 or planarized section F1 are provided at least on either of the front surface or the back surface.

Further, as illustrated in FIG. 6(e), a lens module 88 can be configured by installing the first lens 84 of FIG. 6(a) in a light shielding holder 87. Further, as illustrated in FIG. 6(f), a lens module 89 can be configured by installing a lens module 86A, which is configured of the first lens 61A and the second lens 85A of FIG. 6(b), in the light shielding holder 87. Thus, the lens and the light shielding holder 87 are provided as a set to configure a lens module.

The image capturing element as an electronic element is laminated on either of the first and second lenses 84 and 85 or the lens modules 88 and 89, so that a sensor module as an electronic element module can be obtained.

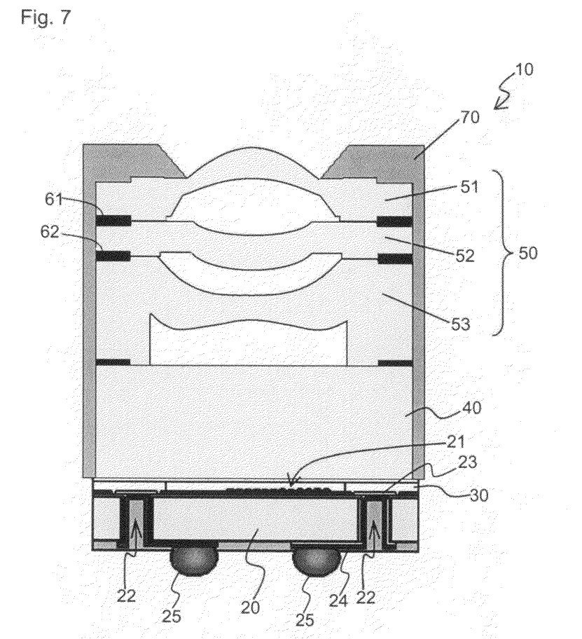

The lens wafer 1 of Embodiment 1 is laminated on the image capturing element wafer as an electronic element wafer to form a sensor wafer module as an electronic element wafer module. The sensor module is simultaneously cut to be individualized and a large number of sensor modules can be simultaneously obtained. The sensor module will be described in detail as Embodiment 2 with reference to FIG. 7.

### Embodiment 3

FIG. 7 is a longitudinal cross sectional view illustrating an exemplary essential part structure of a sensor module according to Embodiment 3 of the present invention.

In FIG. 7, a sensor module 10 as an electronic element module according to Embodiment 3 includes: an image capturing element 21, which includes a plurality of light receiving sections for performing photoelectric conversion on and capturing an image of image light from a subject, disposed at the center portion; an image capturing element chip 20 with a penetrating electrode 22 to the image capturing element 21; a resin adhesion layer 30 formed on the image capturing element chip 20 and between adjacent image capturing elements 21; a transparent support substrate 40, such as a glass plate, covering the image capturing element chip 20 and adhered and fixed on the resin adhesion layer 30; a lens module 50 provided to correspond to the image capturing element 21.

With regard to the image capturing element chip 20, the image capturing element 21 (in which a plurality of light receiving sections are disposed, each of which constitutes a plurality of pixels) is disposed at the center portion on the front surface, and a pad 23 is connected to the image capturing element 21. A plurality of through holes are formed, penetrating from the back surface to below the pad 23 (electrode pad) of the front surface. The side wall of the through hole and the back surface side are covered with an insulation film. A wiring layer 24 in contact with the pad 23 is formed as a penetrating electrode 22 through the through hole up to the back surface. An insulation film is formed on the wiring layer 24 and the back surface, and a portion where a solder ball 25 is formed on an external connection terminal of the wiring layer 24 is not covered with the insulation film, but the solder ball 25 is formed thereon exposed to the outside.

The resin adhesion layer 30 is formed in the peripheral portion of the image capturing element 21 on the front surface, and adheres the image capturing element chip 20 and the transparent support substrate 40. When the upper part of the semiconductor surface is covered by the transparent support substrate 40, the inner space above the sensor area is sealed by the resin adhesion layer 30, where the image capturing element 21 is disposed as an electronic element on the image capturing element chip 20. The resin adhesion layer 30 is formed at a predetermined position on the image capturing element chip 20 using an ordinary photolithography technique, and the transparent support substrate 40 is adhered thereon. The resin adhesion layer 30 can also be formed using a screen printing method and a dispensing method other than the photolithography technique.

The lens module 50 is a module in which three of the lens wafers 1 according to Embodiment 1 are laminated, and a first lens 51, a second lens 52 and a third lens 53 are disposed in order from the top on the transparent support substrate 40. Each of the lenses 51 to 53 includes a lens area provided at the center portion and a spacer section with a predetermined thickness is disposed on an outer circumference side of the lens area. The third lens 53 is an aberration correction lens, the second lens 52 is a diffusion lens, and the first lens 51 is a light focusing lens; and the spacer sections with a predetermined thickness, which are disposed on the outer circumference side of the respective lenses, are laminated and disposed in this order from the bottom. The first lens 51 and the second lens 52 are adhered by an adhesion layer 61 and the second lens 52 and the third lens 53 are adhered by an adhesion layer 62.

### Embodiment 4

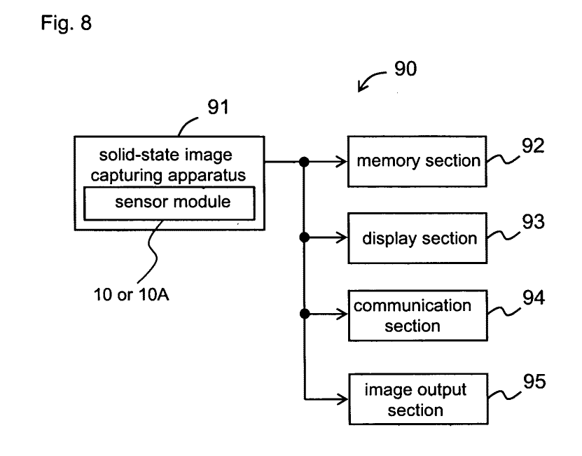

FIG. 8 is a block diagram schematically illustrating an exemplary configuration of an electronic information device of Embodiment 4 of the present invention, including a solid-state image capturing apparatus including the sensor module 10 in which the lens module 50 is combined with the image capturing element chip 20, according to Embodiment 3 of the present invention, or the sensor module 10A in which the lens and lens module according to Embodiment 2 are combined with the image capturing element chip, used in an image capturing section thereof.

In FIG. 8, an electronic information device 90 according to Embodiment 4 of the present invention includes: a solid-state image capturing apparatus 91 for performing various signal processing on an image capturing signal from the sensor module 10 according to Embodiment 3 of the present invention, or the sensor module 10A according to Embodiment 2 of the present invention, so as to obtain a color image signal; a memory section 92 (e.g., recording media) for data-recording a color image signal from the solid-state image capturing apparatus 91 after a predetermined signal processing is performed on the color image signal for recording; a display section 93 (e.g., a liquid crystal display apparatus) for displaying the color image signal from the solid-state image capturing apparatus 91 on a display screen (e.g., liquid crystal display screen) after predetermined signal processing is performed on the color image signal for display; a communication section 94 (e.g., a transmitting and receiving device) for communicating the color image signal from the solid-state image capturing apparatus 91 after predetermined signal processing is performed on the color image signal for communication; and an image output section 95 (e.g., a printer) for printing the color image signal from the solid-state image capturing apparatus 91 after predetermined signal processing is performed for printing. Without any limitations to this, the electronic information device 90 may include any of the memory section 92, the display section 93, the communication section 94, and the image output section 95, such as a printer, other than the solid-state image capturing apparatus 91.

As the electronic information device 90, an electronic information device that includes an image input device is conceivable, such as a digital camera (e.g., digital video camera or digital still camera), an image input camera (e.g., a monitoring camera, a door phone camera, a camera equipped in a vehicle, or a television camera), a scanner, a facsimile machine, a camera-equipped cell phone device, a television telephone device or a personal digital assistance (FDA).

Therefore, according to Embodiment 4 of the present invention, the color image signal from the solid-state image capturing apparatus 91 can be: displayed on a display screen properly by the display section 93, printed out on a sheet of paper using an image output section 95, communicated properly as communication data via a wire or a radio by the communication section 94, stored properly at the memory section 92 by performing predetermined data compression processing; and various data processes can be properly performed.

Without the limitation to the electronic information device 90 according to Embodiment 4 described above, an electronic information device, such as a pick up apparatus including the electronic element module according to the present invention used in an information recording and reproducing section thereof, is also conceived. An optical element of the pick up apparatus in this case is an optical function element (hologram optical element, for example) that directs output light straight to be output and refracting and guiding incident light in a predetermined direction. In addition, as the electronic element of the pick up apparatus, a light emitting element (semiconductor laser element or laser chip, for example) for emitting output light and a light receiving element (photo IC, for example) for receiving incident light are included.

According to Embodiment 1 with the structure described above, part or all of the side surface of the resin replica 14 is buried in the plurality of recesses 11a carved in the base 11 to form the resin replica 14. Therefore, the contacting area of the base 11 and the resin replica 14 is larger than the contacting area of the resin replica 14 and the master mold 13, and the contacting area of the base 11 and the resin replica 14 is larger than the contacting area of the resin replica 14 and the stamper molds 15 and 16. Thus, the release of the master mold 13 and stamper molds 15 and 16 can be performed smoothly and the thickness of the connecting portion 4 between the planarized portions 3 becomes thicker by an amount equal to the depth of the recess 11a. As a result, it becomes possible to accurately form the side surface of the resin replica 14 and accurately form the upper and lower stamper molds 15 and 16. Furthermore, it becomes possible to solve the problem of the strength issue in forming a large-sized lens wafer. Furthermore, it becomes possible to solve the problem of residual the air bubbles by reducing the difference in level (D1−D2) on the surface.

Although not specifically described in Embodiments 1 to 4, a method for manufacturing the optical element wafer includes: a replica forming step of forming a replica with an optical element shape formed on the front surface side thereof in a plurality of recesses formed in the base; a stamper mold forming step of forming a stamper mold by using each optical element shape of the replica; and an optical element wafer forming step of transferring the optical element shape to an optical element material using the stamper mold to form an optical element wafer. As a result, it becomes possible to accurately form the resin replica and accurately form the upper and lower stamper molds. Furthermore, it becomes possible to achieve the objective of solving the problem of the strength issue and the problem of residual the air bubbles in forming a large-sized lens wafer.

As described above, the present invention is exemplified by the use of its preferred Embodiments 1 to 4. However, the present invention should not be interpreted solely based on Embodiments 1 to 4 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 4 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of an optical element wafer, such as a lens wafer or an optical function element wafer, including a plurality of lenses as a plurality of optical elements for focusing incident light; a method for manufacturing the optical element wafer; an optical element individualized by simultaneous cutting from the optical element wafer; an optical element module individualized by simultaneous cutting from an optical element wafer module in which the plurality of optical element wafers are laminated; an electronic element wafer module, such as a sensor wafer module, which is a combination of an optical element or an optical element module and an image capturing element wafer provided with a plurality of image capturing elements for performing a photoelectric conversion on and capturing an image of image light from a subject; an electronic element module individualized by simultaneous cutting from the electronic element wafer module; and an electronic information device, such as a digital camera (e.g., a digital video camera or a digital still camera), an image input camera, a scanner, a facsimile machine, a camera-equipped cell phone device or a television telephone device, including the sensor module as an electronic element module used as an image input device in an image capturing section thereof. According to the present invention, part or all of the side surface of the replica is buried in the respective recesses carved in the base to form the replica, so that the contacting area of the base and the replica becomes larger than the contacting area of the replica and the master mold and the contacting area of the base and the replica becomes larger than the contacting area of the replica and the stamper mold. Thus, the release of the master mold and stamper mold can be performed smoothly and the thickness of the connecting portion between the planarized portions becomes thicker by an amount equal to the depth of the recess, so that it becomes possible to accurately form the replica and accurately form the upper and lower stamper molds; it becomes possible to solve the problem of the strength issue in forming a large-sized lens wafer; and it becomes possible to solve the problem of residual the air bubbles by reducing the difference in level on the surface.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A method for manufacturing an optical element wafer in which a plurality of optical elements are arranged in two dimensions; the method comprising:
a replica forming step of forming a replica, in which an optical element shape is formed on a front surface side, in each of a plurality of recesses formed in a base;
a stamper mold forming step of forming a stamper mold using the optical element shape of the replica; and
an optical element wafer forming step of transferring the optical element shape to an optical element material using the stamper mold to form the optical element wafer.

2. A method for manufacturing the optical element wafer according to claim 1, wherein the replica forming step includes: an upper replica forming step of forming an upper replica, in which an optical element shape is formed on a front surface side, in each of the plurality of recesses formed in the base; and a lower replica forming step of forming a lower replica, in which an optical element shape for a back surface is formed on a front surface side, in each of a plurality of recesses formed in another base.

3. A method for manufacturing the optical element wafer according to claim 1, wherein the replica forming step includes: a step of delivering a replica material in the plurality of recesses formed in the base; and an optical element shape transferring step of pressing the replica material using a master mold to transfer the optical element shape of the master mold to the front surface side of the replica material.

4. A method for manufacturing the optical element wafer according to claim 1, wherein part or all of a side surface of the replica is buried in each of the plurality of recesses carved in the base to form the replica.

5. A method for manufacturing the optical element wafer according to claim 1, wherein a depth of the recess in the base is set such that a contacting area of the base and the replica is larger than a contacting area of the replica and a master mold.

6. A method for manufacturing the optical element wafer according to claim 1, wherein a depth of the recess in the base is set such that a contacting area of the base and the replica is larger than a contacting area of the replica and the stamper mold.

7. A method for manufacturing the optical element wafer according to claim 2, wherein the stamper mold forming step includes: an upper stamper mold forming step of transferring the optical element shape of the upper replica to form an upper stamper mold; and a lower stamper mold forming step of transferring the optical element shape of the lower replica to form a lower stamper mold.

8. A method for manufacturing the optical element wafer according to claim 7, wherein the optical element wafer forming step includes: an optical element material pressing step of pressing the optical element material to a predetermined thickness using the upper stamper mold and the lower stamper mold; and an optical element material curing step of curing the optical element material by light or heat.

9. A method for manufacturing the optical element wafer according to claim 1, wherein the optical element is one or a plurality of lenses.

10. A method for manufacturing the optical element wafer according to claim 1, wherein the optical element is an optical function element that directs output light straight to be output and refracts and guides incident light in a predetermined direction.

11. An optical element wafer manufactured using the method for manufacturing the optical element wafer according to claim 1.

12. An optical element wafer, in which a plurality of optical elements are arranged in two dimensions, the optical element wafer including:
a plurality of optical element areas at least on either a front surface or a back surface of the optical element wafer;
a planarized portion with a predetermined thickness provided on an outer circumference side of the optical element area, and
wherein a thickness of the planarized portion between adjacent optical element areas and a thickness of a connecting portion between the planarized portions are within the ratio of 2:1 to an equal ratio.

13. An optical element wafer according to claim 12, wherein the thickness of the planarized portion between the adjacent optical element areas is within the ratio of 4/3 or 3/4 to an equal ratio with the thickness of the connecting portion between the planarized portions.

14. An optical element wafer according to claim 12, wherein the optical element is one or a plurality of lenses.

15. An optical element wafer according to claim 12, wherein the optical element is an optical function element that directs output light straight to be output and refracts and guides incident light in a predetermined direction.

16. An optical element individualized by cutting from the optical element wafer according to claim 11, the optical element including: an optical surface at a center portion; and a spacer section with a predetermined thickness on an outer circumference side of the optical surface.

17. An optical element individualized by cutting from the optical element wafer according to claim 12, the optical element including: an optical surface at a center portion; and a spacer section with a predetermined thickness on an outer circumference side of the optical surface.

18. An optical element module individualized by cutting an optical element wafer module, in which the plurality of optical element wafers according to claim 11 are laminated with optical surfaces thereof being aligned to one another.

19. An optical element module individualized by cutting an optical element wafer module, in which the plurality of optical element wafers according to claim 12 are laminated with optical surfaces thereof being aligned to one another.

20. An optical element module according to claim 18, further including alight shielding holder for shielding an upper surface other than an upper most optical surface, and side surfaces of the plurality of optical elements.

21. An optical element module according to claim 19, further including alight shielding holder for shielding an upper surface other than an upper most optical surface, and side surfaces of the plurality of optical elements.

22. An optical element module including a light shielding holder for shielding an upper surface other than the optical surface, and side surfaces of the optical element according to claim 16.

23. An optical element module including a light shielding holder for shielding an upper surface other than the optical surface, and side surfaces of the optical element according to claim 17.

24. An electronic element wafer module, comprising:
an electronic element wafer in which a plurality of electronic elements are arranged, the electronic elements each including a penetrating electrode;
a resin adhesion layer formed in a predetermined area on the electronic element wafer;
a transparent support substrate covering the electronic element wafer and fixed on the resin adhesion layer;
an optical element wafer according to claim 11, adhered and combined with the transparent support substrate such that each of the plurality of electronic elements corresponds to each optical element.

25. An electronic element wafer module, comprising:
an electronic element wafer in which a plurality of electronic elements are arranged, the electronic elements each including a penetrating electrode;
a resin adhesion layer formed in a predetermined area on the electronic element wafer;
a transparent support substrate covering the electronic element wafer and fixed on the resin adhesion layer;
an optical element wafer according to claim 12, adhered and combined with the transparent support substrate such that each of the plurality of electronic elements corresponds to each optical element.

26. An electronic element wafer module according to claim 24, wherein the optical element wafer is a lens wafer module constituted of three lenses of an aberration correction lens, a diffusion lens and a light focusing lens; in which planarized portions with a predetermined thickness are provided on an outer circumference side of each of the lenses is laminated in this order from the bottom.

27. An electronic element wafer module according to claim 25, wherein the optical element wafer is a lens wafer module constituted of three lenses of an aberration correction lens, a diffusion lens and a light focusing lens; in which planarized portions with a predetermined thickness are provided on an outer circumference side of each of the lenses is laminated in this order from the bottom.

28. An electronic element wafer module according to claim 24, wherein the electronic element is an image capturing element including a plurality of light receiving sections for performing a photoelectric conversion on and capturing an image of image light from a subject.

29. An electronic element wafer module according to claim 25, wherein the electronic element is an image capturing element including a plurality of light receiving sections for performing a photoelectric conversion on and capturing an image of image light from a subject.

30. An electronic element wafer module according to claim 24, wherein each of said electronic elements is a light emitting element for generating output light and a light receiving element for receiving incident light.

31. An electronic element wafer module according to claim 25, wherein each of said electronic elements is a light emitting element for generating output light and a light receiving element for receiving incident light.

32. An electronic element module cut from the electronic element wafer module according to claim 11, for each or a plurality of the electronic element modules.

33. An electronic element module cut from the electronic element wafer module according to claim 12, for each or a plurality of the electronic element modules.

34. An electronic information device including an electronic element module, which is individualized by being cut from the electronic element wafer module according to claim 28, used as a sensor module in an image capturing section.

35. An electronic information device including an electronic element module, which is individualized by being cut from the electronic element wafer module according to claim 29, used as a sensor module in an image capturing section.

36. An electronic information device including an electronic element module, which is individualized by being cut from the electronic element wafer module according to claim 30, used in an information recording and reproducing section.

37. An electronic information device including an electronic element module, which is individualized by being cut from the electronic element wafer module according to claim 31, used in an information recording and reproducing section.
